(19) United States
(12) Patent Application Publication
(10) Pub. No.: US 2019/0387650 A1
(43) Pub. Date: Dec. 19, 2019

(54) HEAT SINK FOR PLUGGABLE MODULE CAGE

(71) Applicant: CISCO TECHNOLOGY, INC., San Jose, CA (US)

(72) Inventors: Xiaoxia Zhou, Shanghai (CN); Hailong Zhang, Shanghai (CN); Jianquan Lou, Shanghai (CN); Huasheng Zhao, Shanghai (CN); Luli Gong, Shanghai (CN); Yonghong Luo, Shanghai (CN)

(73) Assignee: CISCO TECHNOLOGY, INC., San Jose, CA (US)

(21) Appl. No.: 16/008,203

(22) Filed: Jun. 14, 2018

(51) Int. Cl. H05K 9/00; G02B 6/42; H05K 7/20

(52) U.S. Cl. CPC H05K 9/0058; G02B 6/4261; H01R 13/6582; G02B 6/428; H05K 7/20418; G02B 6/4269

(57) ABSTRACT

In one embodiment, an apparatus includes a housing for receiving pluggable modules, the housing comprising at least one lower opening and at least one upper opening, each of the openings configured to receive one of the pluggable modules, and a heat sink interposed between the lower and upper openings. The heat sink comprises a cross-sectional honeycomb structure defining cooling tubes extending longitudinally between parallel surfaces of the heat sink for dissipating heat from the pluggable modules inserted into the lower and upper openings.

### TECHNICAL FIELD

The present disclosure relates generally to communications networks, and more specifically to a heat sink for use in a pluggable module cage.

### BACKGROUND

Over the past several years, there has been a tremendous increase in the need for higher performance communications networks. To satisfy the increasing demand of bandwidth and speed, pluggable transceiver modules are being used in line cards on various network devices (e.g., switches, routers, etc.). The pluggable transceiver modules are used to convert electrical signals to optical signals or in general as the interface to a network element copper wire or optical fiber. Increased performance requirements have also led to an increase in energy use resulting in greater heat dissipation from the pluggable modules.

### BRIEF DESCRIPTION OF THE DRAWINGS

FIG. 1 is a perspective of a pluggable module cage, in accordance with one embodiment.

FIG. 2A is a front view of a heat sink for use in the pluggable module cage of FIG. 1, in accordance with one embodiment.

FIG. 2B is a perspective of the heat sink shown in FIG. 2A.

FIG. 3 shows the heat sink installed in the pluggable module cage.

FIG. 4A is a perspective of the heat sink installed in the pluggable module cage from a rear view with a portion of the cage removed to show the heat sink.

FIG. 4B is a perspective of the heat sink installed in the pluggable module cage from a front view with a portion of the cage removed to show the heat sink.

FIG. 5 is a cutaway view of the pluggable module cage taken through line 5-5 in FIG. 1, showing the heat sink installed in the cage.

FIG. 6 is a perspective of the heat sink with a conductive elastomer gasket installed between the heat sink and a central compartment of the pluggable module cage.

FIG. 7 is a block diagram of the pluggable module cage mounted on a circuit board with two pluggable modules inserted therein.

FIG. 8A is a graph showing thermal performance with the heat sink installed in the pluggable module cage compared to a conventional pluggable module cage assembly.

FIG. 8B is a graph showing EMI performance with the heat sink installed in the pluggable module cage compared to a conventional pluggable module cage assembly.

Corresponding reference characters indicate corresponding parts throughout the several views of the drawings.

### DESCRIPTION OF EXAMPLE EMBODIMENTS

### Overview

In one embodiment, an apparatus generally comprises a housing for receiving pluggable modules, the housing comprising at least one lower opening and at least one upper opening, each of the openings configured to receive one of the pluggable modules, and a heat sink interposed between the lower and upper openings. The heat sink comprises a cross-sectional honeycomb structure defining cooling tubes extending longitudinally between parallel surfaces of the heat sink for dissipating heat from the pluggable modules inserted into the lower and upper openings.

In another embodiment, an apparatus generally comprises an optical module cage comprising a housing with a lower port and an upper port for receiving optical modules and a heat sink interposed between the lower and upper ports. The apparatus further comprises the optical modules inserted into the lower and upper ports. The heat sink comprises a cross-sectional honeycomb structure defining cooling tubes extending longitudinally along the housing and generally parallel to the optical modules, the heat sink comprising a lower surface positioned above the lower port and an upper surface positioned below the upper port to dissipate heat from the optical modules inserted into the lower and upper ports.

In yet another embodiment, an apparatus generally comprises a housing comprising stacked openings for receiving optical modules and a central compartment interposed between the stacked openings, and a heat sink located within the central compartment and comprising a block with a plurality of air flow channels formed therein and extending from a front face of the block to a rear face of the block. The heat sink comprises at least two rows of the air flow channels with each of the rows comprising a plurality of the air flow channels for dissipating heat from the optical modules when inserted into the stacked openings.

Further understanding of the features and advantages of the embodiments described herein may be realized by reference to the remaining portions of the specification and the attached drawings.

### Example Embodiments

The following description is presented to enable one of ordinary skill in the art to make and use the embodiments. Descriptions of specific embodiments and applications are provided only as examples, and various modifications will be readily apparent to those skilled in the art. The general principles described herein may be applied to other applications without departing from the scope of the embodiments. Thus, the embodiments are not to be limited to those shown, but are to be accorded the widest scope consistent with the principles and features described herein. For purpose of clarity, details relating to technical material that is known in the technical fields related to the embodiments have not been described in detail.

Pluggable modules come in many different form factors such as SFP (Small Form-Factor Pluggable), QSFP (Quad Small Form-Factor Pluggable), CFP (C Form-Factor Pluggable), and the like, and may support data rates up to 400 Gb/s, for example. The pluggable transceiver modules operate as an engine that converts electrical signals to optical signals or in general as the interface to the network element copper wire or optical fiber. Hosts for these pluggable modules include line cards used on switches, routers, edge products, and other network devices.

As telecommunication systems speeds and power requirements increase, the emission from the pluggable module increases along with a need for improved cooling. For example, as speeds and power requirements increase, 25G/100G ports are widely being used in core switches and routers, and the emission from an SFP vent hole is becoming more of an issue. Also, due to increases in system power requirements, additional air-vent openings are needed for increased air-flow and improved cooling in a QFP (Quad Flat Package) panel.

The embodiments described herein provide a heat sink configured for use with a pluggable module (e.g., optical module, SFP). As described below, the heat sink may be located in a mezzanine of a pluggable module cage (e.g., interposed between two stacked SFPs in an optical module cage) and comprises a honeycomb structure. The heat sink enhances thermal and radiation performance without increasing costs for pluggable module cages.

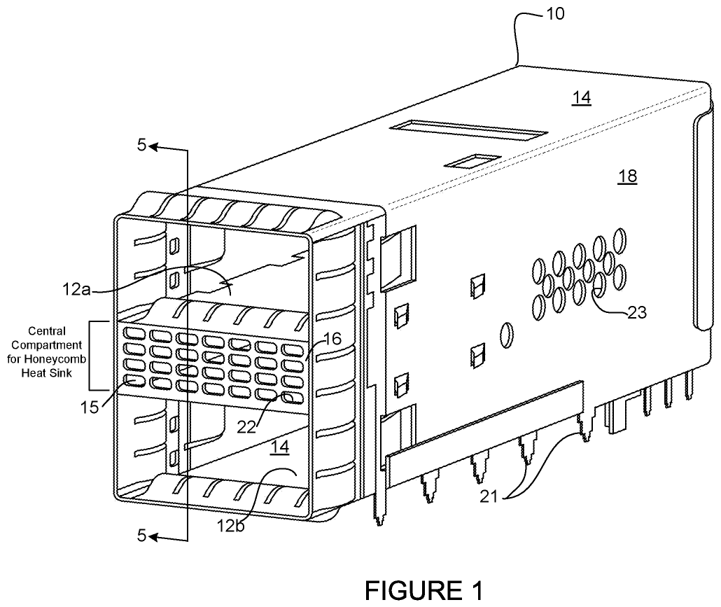

Referring now to the drawings, and first to FIG. 1, a cage structure for receiving two pluggable modules (optical modules, optics modules, pluggable optical modules, optical transceivers (e.g., SFPs, QSFPs, CFPs, and the like)) is shown. The cage structure includes a housing 10 comprising openings (ports) 12a, 12b for receiving the optical modules. In the example shown in FIG. 1, the cage (pluggable module cage, optical module cage) comprises two openings 12a, 12b for receiving two pluggable modules, one into each of the openings in a stacked configuration. Although two openings are illustrated herein, the cage may include additional openings in a stacked arrangement (e.g., 2×2 (two rows, two modules in reach row), 2×4 (two rows, four modules in each row, etc.). The term “stacked” as used herein refers to one module positioned in a location above another module. It is to be understood that the terms above/below or upper/lower as used herein are relative to the position of the cage and also cover other orientations of the cage. For example, if the cage is turned on its side the upper and lower openings would be side by side.

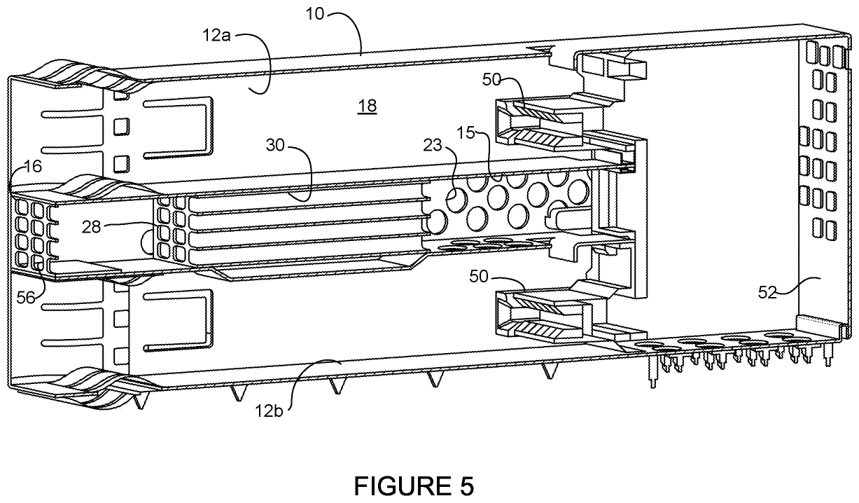

The cage housing 10 also comprises connectors (interfaces) (described below with respect to FIG. 5) for connecting the optical modules with electronic components used in an optical node that may emit electromagnetic energy and heat. The electronic components may comprise a host (e.g., one or more integrated circuit cards mounted on one or more circuit boards along with supporting components) (not shown in FIG. 1). For example, the host may comprise a line card or other electronic component operable to utilize transceivers and interface with a telecommunications network. The host may include a printed circuit board (PCB) and electronic components and circuits operable to interface telecommunication lines (e.g., copper wire, optical fibers) in a telecommunications network. The host may be configured to perform one or more operations and comprise one or more components (e.g., electrical elements of a high speed digital to analog converter to digitize a received signal, high speed digital signal processor (DSP) to reconstruct transmitted information, etc.) and may be configured to receive any number or type of pluggable transceiver modules (e.g., SFP, QSFP, CFP, etc.) configured for transmitting and receiving signals. The pluggable module may be configured to support gigabit Ethernet, Fibre Channel, or other communication standards.

The host may be configured for operation in any type of chassis or network device (e.g., router, switch, gateway, controller, edge device, access device, aggregation device, core node, intermediate node, or other network device). The network device may comprise any number of hosts and operate in the context of a data communications network including multiple network devices. The network device may communicate over one or more networks (e.g., local area network (LAN), metropolitan area network (MAN), wide area network (WAN), virtual private network (VPN) (e.g., Ethernet virtual private network (EVPN), layer 2 virtual private network (L2VPN)), virtual local area network (VLAN), wireless network, enterprise network, corporate network, data center, Internet, intranet, radio access network, public switched network, or any other network).

Referring again to FIG. 1, the upper and lower openings 12a, 12b (ports) are defined by upper and lower walls 14 and central compartment 15, which extend between and are connected to the side walls 18. The central compartment 15 (also referred to as a mezzanine or cooling compartment/channel) allows air flow through the cage (e.g., from front to rear (e.g., side openings 23) or rear to front of the central compartment). In a 2×1 stacked configuration, side air flow through openings 23 in the side wall 18 may also provide cooling. As described in detail below, a heat sink comprising a plurality of air flow channels (cooling tubes) in a honeycomb cross-sectional structure is contained within the central compartment 15 and positioned therein to increase thermal dissipation and decrease EMI (Electromagnetic Interference). In the example shown in FIG. 1, the cage includes a front grill 16 extending over the central compartment 15 and comprising openings to allow airflow through the heat sink. A rear face of the cage may also include openings to further aid in air flow through the central compartment 15. The cage (housing) 10 further includes ground points 21 for interface with a circuit board.

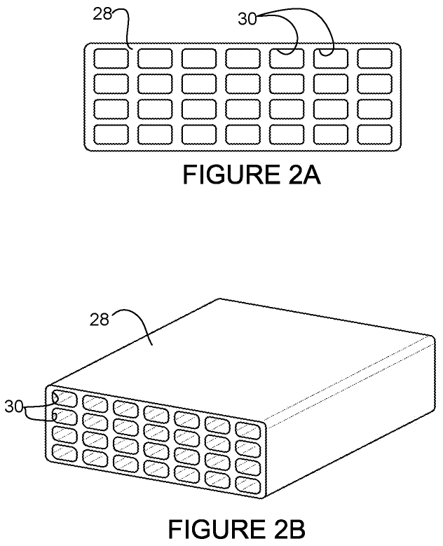

FIG. 2A is a front view and FIG. 2B is a perspective of a heat sink 28, in accordance with one embodiment. The heat sink 28 comprises a lattice (honeycomb) cross-sectional structure forming a plurality of cooling tubes (air flow channels) 30 that extend the length of the heat sink and transfer heat away from a heat source (e.g., optical modules, pluggable modules, transceivers) installed in ports 12a, 12b in the housing 10 (FIGS. 1, 2A, 2B).

As shown in FIG. 2B, the heat sink comprises a block with the air flow channels 30 formed therein and extending from a front face of the block to a rear face of the block. The heat sink 28 comprises at least two rows of air flow channels 30 with each row comprising a plurality air flow channels for dissipating heat from the optical modules when inserted into the ports. The cooling channels 30 define a plurality of individually stacked airflow passages that extend longitudinally along a portion of the length of the pluggable module cage housing. In order to dissipate heat, the heat sink 28 allows for airflow along its length. In the example shown in FIGS. 2A and 2B, the honeycomb structure 28 comprises a 4×7 array of generally rectangular shaped passages (in cross-section) with rounded corners. It is to be understood that the shape, size, arrangement, or number of openings is only an example, and that honeycomb geometries with different cross-sectional shapes or arrays may be used without departing from the scope of the embodiments.

The heat sink 28 may, for example, be formed from copper, aluminum, or another suitable material and made by die-casting or another compatible manufacturing process.

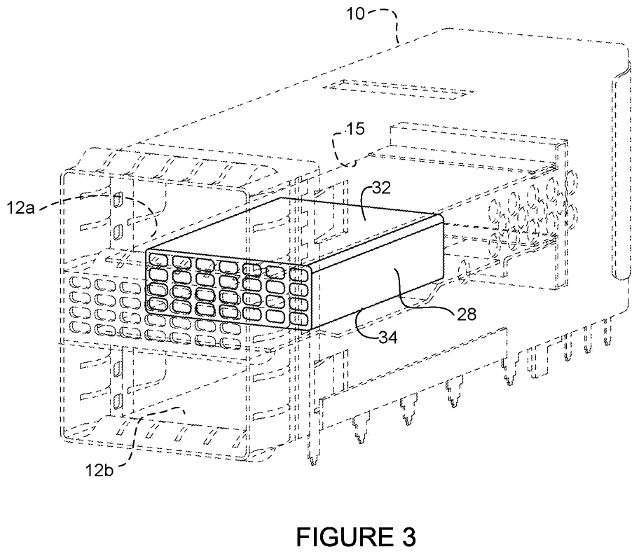

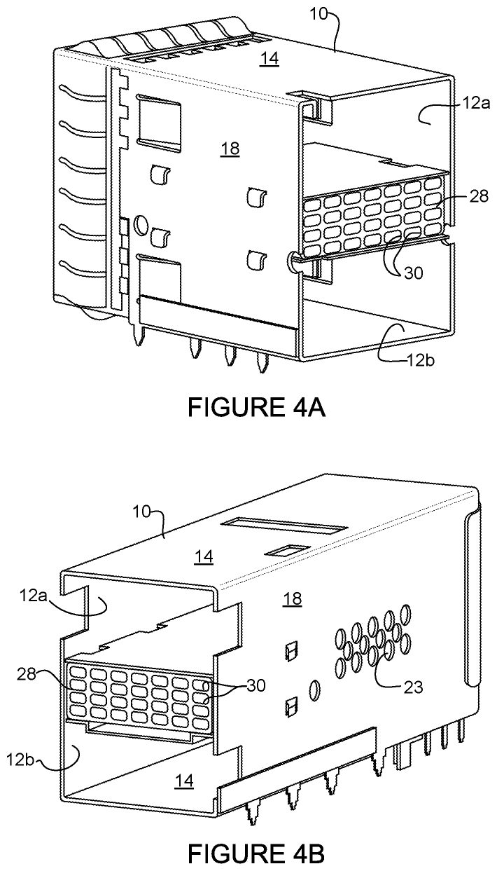

FIGS. 3, 4A and 4B illustrate the heat sink 28 positioned within the cage 10. FIGS. 4A and 4B show the heat sink 28 and cage 10 from a rear perspective and front perspective, respectively, with portions of the housing 10 removed to show the heat sink (rear face of the heat sink shown in FIG. 4A and front face of the heat sink shown in FIG. 4B). The heat sink 28 dissipates heat from electronic components installed in the ports 12a, 12b to a cooler environment (e.g., ambient air). Thermal performance is improved due to the larger dissipation area provided by the honeycomb structure forming the plurality of stacked air flow channels (cooling tubes) 30. Importantly, the design and location of the heat sink 28 within the pluggable module cage 10 allows the heat sink to dissipate heat for both the upper and lower modules. For example, as shown in FIG. 3, the cooling tubes 30 extend longitudinally between parallel surfaces of the heat sink (an upper surface 32 positioned below the upper opening 12a and a lower surface 34 positioned above the lower opening 12b) such that each of the surfaces is positioned generally adjacent to the pluggable modules when the modules are inserted into the openings to dissipate heat from both pluggable modules.

The heatsink also improves EMC (Electromagnetic Compatibility) shielding by reducing the radiation from the mezzanine 15. In one or more embodiments, EMI performance may be sacrificed somewhat (e.g., by providing larger openings in the heat sink 28) for better thermal performance.

FIG. 5 is a cross-sectional view of the housing 10 and heat sink 28. The optical modules are received in the upper and lower openings 12a, 12b and positioned adjacent to the heat sink 28 (either above or below). The optical modules connect to electrical components through connectors (mating interfaces) 50. As shown in FIG. 5, the heat sink 28 is positioned spaced from the grill 16. The longitudinal passageways 30 in the heat sink 28 allow air flow through the heat sink so that heat (thermal energy) can dissipate externally from the housing (e.g., through the front grill 16 or openings 23 in the side wall). As shown in FIG. 5, the cooling tubes (air flow channels) 30 are defined by material of the heat sink surrounding each of the tubes, which extend longitudinally in the central compartment of the housing and are open only at a front face and rear face of the heat sink 28. In one example, the channels 30 in the heat sink generally align with openings 56 in the grill 16.

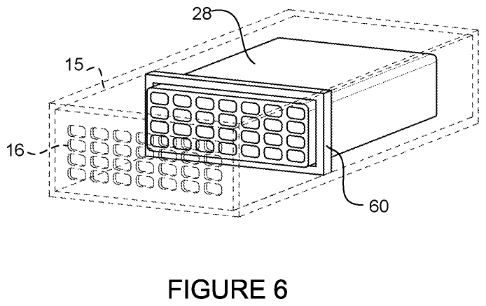

In one or more embodiments, a conductive elastomer gasket 60 extends around the periphery of the heat sink 28 to ensure contact between the heat sink and central compartment of the cage for improved EMI performance, as shown in FIG. 6.

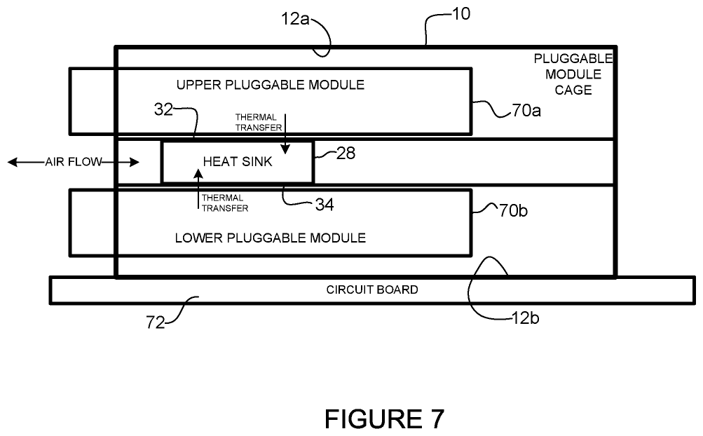

FIG. 7 is a schematic side view of pluggable modules 70a and 70b inserted into ports 12a, 12b in the pluggable module cage 10. The heat sink 28 is interposed between the upper and lower modules 70a, 70b and the pluggable module cage 10 is mounted on a circuit board 72. As previously described, the upper and lower surfaces 32, 34 of the heat sink 28 are positioned adjacent to the ports 12a, 12b so that energy is dissipated from both the upper and lower pluggable modules 70a, 70b. Air flowing through the cooling tubes of the heat sink 28 generally parallel to the optical modules 70a, 70b dissipates thermal energy from the heat sink. Thermal energy is thus transferred from the pluggable modules 70a, 70b into the heat sink 28 and flows out of the cage taking away at least a portion of the thermal energy.

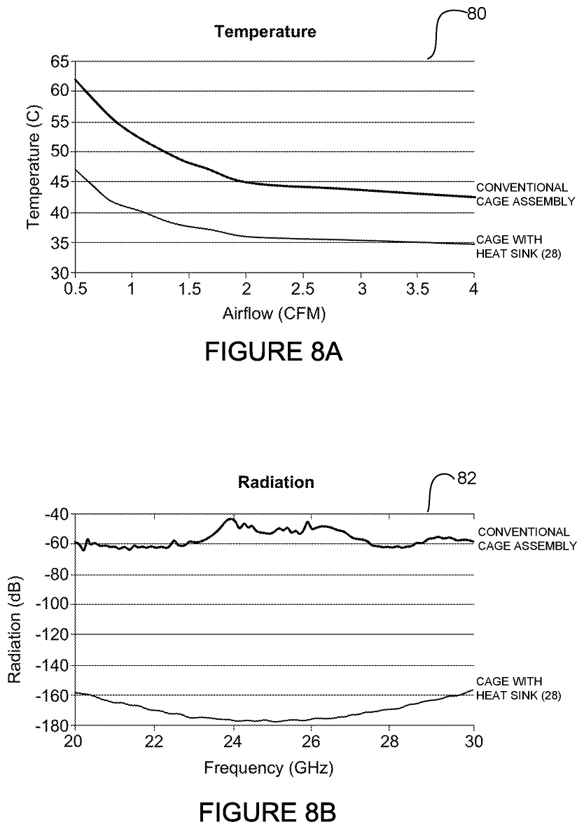

FIG. 8A shows a graphical plot 80 illustrating a comparison of thermal performance between the heat sink 28 described herein and a conventional cage assembly. The new heat sink design increases dissipation area thereby decreasing module temperature by about ten degrees, as verified by thermal simulation with airflow from 0.5 CFM (cubic feet per minute) to 4 CFM.

FIG. 8B shows a graphical plot 82 illustrating a comparison of electromagnetic radiation between the heat sink 28 described herein and a conventional cage assembly. The heat sink 28 provides a long waveguide that increases radiation attenuation and thereby decreases radiation. In an EMC simulation the total radiated power of an optical module cage assembly with the new heat sink 28 improved by about 100 dB.

As can be observed from the foregoing, one or more embodiments may provide numerous advantages over conventional pluggable module cage designs. For example, thermal performance is improved due to a larger dissipation area. Also, since the heat sink includes an upper and lower base, the heat sink is able to dissipate heat from both upper and lower modules. The long waveguide of the heat sink increases attenuation thereby improving EMI performance.

Although the method and apparatus have been described in accordance with the embodiments shown, one of ordinary skill in the art will readily recognize that there could be variations made to the embodiments without departing from the scope of the invention. Accordingly, it is intended that all matter contained in the above description and shown in the accompanying drawings shall be interpreted as illustrative and not in a limiting sense.

1: An apparatus comprising:
a housing for receiving pluggable modules, the housing comprising at least one lower opening and at least one upper opening, each of said openings configured to receive one of the pluggable modules; and
a heat sink located in a mezzanine of the housing interposed between said lower opening and said upper opening;
wherein the heat sink comprises a block comprising an array of generally rectangular shaped openings defining at least two rows of cooling tubes extending longitudinally between parallel upper and lower surfaces of the heat sink for dissipating heat from the pluggable modules inserted into said lower and upper openings adjacent to said upper and lower surfaces of the heat sink.

2: The apparatus of claim 1 wherein the housing comprises two rows of stacked openings for receiving at least four pluggable modules.

3: The apparatus of claim 1 wherein the heat sink comprises at least four rows of said cooling tubes extending through the heat sink.

4. (canceled)

5: The apparatus of claim 1 wherein said array corresponds to openings in a grill positioned in front of the heat sink in the housing.

6: The apparatus of claim 1 further comprising a gasket extending around a periphery of the heat sink to provide contact between the heat sink and a central compartment supporting the heat sink in the housing.

7: The apparatus of claim 6 wherein the gasket comprises a conductive elastomer for improving EMI (electromagnetic interference) performance.

8: The apparatus of claim 1 wherein the cooling tubes define a plurality of long waveguides for increasing radiation attenuation and thermal dissipation.

9: An apparatus comprising:
an optical module cage comprising:
a housing comprising a lower port and an upper port for receiving optical modules; and
a heat sink located in a mezzanine of the housing interposed between said lower and upper ports; and
the optical modules inserted into said lower and upper ports;
wherein the heat sink comprises a block comprising an array of generally rectangular shaped openings defining at least two rows of cooling tubes extending longitudinally along the housing and generally parallel to the optical modules, the heat sink comprising a lower surface positioned above said lower port and an upper surface positioned below said upper port to dissipate heat from the optical modules inserted into said lower and upper ports.

10: The apparatus of claim 9 wherein the housing comprises two rows of stacked ports for receiving the optical modules, each of the optical modules comprising an optical transceiver.

11: The apparatus of claim 9 wherein the heat sink comprises at least four rows of cooling tubes extending through the heat sink.

12. (canceled)

13: The apparatus of claim 9 wherein said array corresponds to openings in a grill positioned in front of the heat sink in the housing.

14: The apparatus of claim 9 further comprising a gasket extending around a periphery of the heat sink to provide contact between the heat sink and a central compartment containing the heat sink.

15: The apparatus of claim 14 wherein the gasket comprises a conductive elastomer for improving EMI (electromagnetic interference) performance.

16: The apparatus of claim 9 wherein the cooling tubes defines a plurality of long waveguides for increasing radiation attenuation and dissipation area.

17: The apparatus of claim 9 wherein the optical module cage is mounted on a circuit board.

18: An optical module cage comprising:
a housing comprising stacked openings for receiving optical modules and a central compartment interposed between said stacked openings; and
a heat sink located within said central compartment and comprising a block with a plurality of air flow channels formed therein and extending from a front face of the block to a rear face of the block, the heat sink comprising an upper surface and a lower surface and at least two rows of said air flow channels therebetween with each of said rows comprising a plurality of said air flow channels for dissipating heat from the optical modules when inserted into said stacked openings.

19: The optical cage of claim 18 wherein each of said air flow channels is surrounded by the block to form cooling tubes open only on said front face and said rear face of the block.

20: The optical cage of claim 18 wherein the heat sink comprises a four by seven array of said air flow channels, wherein the air flow channels comprise generally rectangular shaped openings.

21: The apparatus of claim 1 wherein the block is formed from copper or aluminum to increase thermal dissipation from the pluggable modules.

22: The apparatus of claim 18 wherein the heat sink is positioned spaced from a grill located in front of the heat sink in the housing.
